(19) United States
(12) Patent Application Publication
(10) Pub. No.: US 2025/0243080 A1
(43) Pub. Date: Jul. 31, 2025

(54) CORE-SHELL NANOPARTICLES AND METHODS OF FABRICATION THEREOF

(71) Applicant: National University of Singapore, Singapore (SG)

(72) Inventors: Vivek NAIR, Singapore (SG); Sergio GRANIERO ECHEVERRIGARAY, Singapore (SG); Antonio Hello de CASTRO NETO, Singapore (SG)

(21) Appl. No.: 18/856,234

(22) PCT Filed: Apr. 14, 2023
(86) PCT No.: PCT/SG2023/050253

§ 371 Date: Oct. 11, 2024

(30) Foreign Application Priority Data
Apr. 14, 2022 (SG) 10202203918P

(51) Int. Cl. C01G 33/00

(52) U.S. Cl. CPC C01G 33/006; C01P 2002/72; C01P 2004/61; C01P 2004/62; C01P 2004/64; C01P 2004/84; C01P 2006/40

(57) ABSTRACT

The present disclosure concerns core-shell nanoparticles, each comprising a core comprising Nb and NbS₂; preferably NbS₂ and a shell of Formula NbSₓO_{y}·zH₂O, wherein x is a number from 0 to 5; y is a number from 0 to 3; and z is a number from 0 to 10. The present disclosure also concerns a method of synthesising core-shell nanoparticles.

### TECHNICAL FIELD

The present invention relates, in general terms, to core-shell nanoparticles and composite materials for use as anodes in batteries. The present invention also relates to their methods of fabrication thereof.

### BACKGROUND

The market size for anode materials is higher than 50 billion US dollars as of 2021. The search for high capacity anode materials to build energy-dense cells has resulted in the use of silicon and Li-metal. It is expected that the automotive cells with lithium nickel manganese cobalt oxide (NMC) and lithium nickel cobalt aluminium oxide (NCA) cathodes paired with Si or Li-metal dominant anodes is expected to increase the energy density by up to 50%, thereby dropping the $/kWh cost by 30-40% in less than a decade. Most of the existing Li-Ion batteries use conventional anode material like graphite (intercalation-reaction), typically used as a mixture of natural and synthetic graphite. Graphite provides a specific capacity of 330 mAh/g but presents various problems like dendrite formation and plating of Li-metal, which causes irreversible capacity loss and safety issues.

When alkali and alkaline-earth metals (like Li-metal) are used as anode, it undergoes platting/stripping reaction while the cathode undergoes intercalation/de-intercalation reaction (like in the case of insertion compounds like LiNiMnCoO₂, LiMn₂O₄, LiCoO₂, etc), or conversion reactions like the sulfur cathodes. Most solid-state and Li—S batteries use Li-metal as anode, and so, most of the research and start-ups are involved in solving the critical problems related to it, like irreversible capacity loss, dendrite formation, anode-based cell impedance, stability, etc.

Unlike graphite, silicon does not store lithium ions using an intercalation mechanism. Instead, it operates by a “conversion” mechanism, where silicon and lithium atoms form electrochemical alloys, breaking and restoring chemical bonds during charge-discharge cycling. The conversion name comes from converting or transforming from one structure to another. The bonds made in conversion reactions are much stronger (the reason they can store more energy). However, these bonds are harder to make and break in a repeatable way without long term damage. Attaining Si anode cycle-ability is technically more challenging. Despite the long development history (1953—till date), there are no high-volume commercial Li-ion batteries in which silicon anode entirely replaces graphite. About 1% of the anode materials produced globally today are silicon-based. The silicon is used as an additive to graphite-based cells in small quantities. The Panasonic/Tesla cell contains about 5% silicon in the form of silicon oxide blended to graphite. The major challenge with silicon is that it expands 300% when it reacts with lithium during the charging process and contracts the same 300% during the discharging. By contrast, graphite expands and contracts about 7% in charge and discharge. This swelling causes issues like particle pulverisation, solid-electrolyte interface (SEI) damage, and side reactions that trap lithium, which has prevented silicon from replacing graphite. Cell and battery material makers mix 3-5% silicon into graphite to make anodes and to overcome this challenge. This solution allows the boost of the energy density by about 10-20%. Adding more silicon would drastically reduce the cycle life for any practical applications.

Pure silicon anodes typically cannot achieve more than ˜100 complete charge-discharge cycles and cannot be replicated cost-effectively at scale.

Given the current drive towards electric vehicles, there is a need for batteries with greater storage capacity, better charge-discharge cycling, battery lifespan, and/or reduced weight.

It would be desirable to overcome or ameliorate at least one of the above-described problems.

### SUMMARY

The present invention provides a core-shell nanoparticle, comprising:
a) a core comprising Nb and NbS₂; preferably NbS₂ and
b) a shell of Formula (I):

NbSₓO_{y}·zH₂O (I)
wherein
x is a number from 0 to 5;
y is a number from 0 to 3; and
z is a number from 0 to 10.

In some embodiments, x, y and z are integers.

In some embodiments, the core-shell nanoparticle has a particle size of about 10 nm to about 10000 nm.

In some embodiments, core-shell nanoparticle has a shell thickness of about 5 nm to about 900 nm.

In some embodiments, the core-shell nanoparticle is lithiated.

The present invention also provides a composite material, comprising:
a) a substrate; and
b) the core-shell nanoparticle as disclosed herein in contact with the substrate;
wherein the substrate is selected from graphite, graphene, an alkali metal, an alkaline-earth metal or alloy thereof, and a current collector comprising carbon, metals, intermetallic alloys and alloys and optionally, alkali and alkaline-earth metal.

In some embodiments, the core-shell nanoparticle is dispersed within the substrate.

In some embodiments, the core-shell nanoparticle is formed as a coating on the substrate.

In some embodiments, the coating is characterised by a thickness of about 10 nm to about 500 μm.

In some embodiments, when the core-shell nanoparticle is formed as a coating on the substrate, the substrate is Li metal.

In some embodiments, when the core-shell nanoparticle is formed as a coating on the substrate, the substrate is carbon paper and the coating is characterised by a ratio of the core-shell nanoparticle to carbon black to binder is about 8:1:1.

In some embodiments, when the core-shell nanoparticle is formed as a coating on the substrate, the substrate is Cu foil and the coating is characterised by a ratio of the core-shell nanoparticle to carbon black to binder is about 9:0.5:0.5.

In some embodiments, when the core-shell nanoparticle is formed as a coating on the substrate, the substrate is carbon paper and the coating is characterised by a ratio of the core-shell nanoparticle to graphene to carbon black to binder is about 2:6:1:1.

In some embodiments, the composite material is characterised by an electric conductivity of at least about 100 times higher relative to Li metal.

The present invention also provides a battery, comprising an anode, wherein the anode comprises the core-shell nanoparticle as disclosed herein.

In some embodiments, the battery is characterised by a minimum capacity of at least about 800 mAh/g within a voltage range of about 0.01 V to about 2.8 V.

In some embodiments, the battery is characterised by a stable specific capacity of about 1,000 mAh/g to about 5,000 mAh/g.

In some embodiments, the battery is characterised by a cycling discharge specific stability of at least 45 mAh/g after 20 cycles.

In some embodiments, the battery is characterised by a mid-value-voltage of at least about 10 times lower relative to Li metal.

In some embodiments, the battery is characterised by a cycling stability of at least 300 cycles.

The present invention provide a method of synthesising a core-shell nanoparticle as disclosed herein, comprising:
a) passing sulphur vapour over a Nb metal nanoparticle under an inert condition; and
b) oxidising and hydrating the nanoparticle of step (a) in order to form the core-shell nanoparticle.

In some embodiments, the inert condition is a constant inert gas flow.

In some embodiments, the inert gas is selected from Argon, Nitrogen, or a combination thereof.

In some embodiments, step (a) is performed at about 900° C. to about 1200° C.

In some embodiments, step (b) is performed by exposing the nanoparticles of step (a) to air.

### BRIEF DESCRIPTION OF THE DRAWINGS

Embodiments of the present invention will now be described, by way of non-limiting example, with reference to the drawings in which:

FIG. 1 shows the XRD of NbSₓO_{y}·zH₂O nanoparticles (NbSx).

FIG. 2 shows the galvanic charge-discharge behaviour of NbSx coated over a) carbon paper as a current collector with E1 electrolyte and b) copper as a current collector with A1 electrolyte. The capacity is based on NbSx active material alone.

FIG. 3 shows the galvanic charge-discharge behaviour of NbSx graphene composite coated over carbon current collector using A1 electrolyte.

FIG. 4 shows the galvanic charge-discharge behaviour of NbSx coated over copper current collector using A1 electrolyte and a carbon fibre interlayer between Celgard 2325 separator and anode.

FIG. 5 compares the galvanic charge-discharge behaviour of NbSx and NbSx graphene composite anode materials against NMC532 single crystal in a full cell configuration using A1 electrolyte.

FIG. 6 compares the rate, cycling performance and Coulombic efficiency of commercial graphite, NbSx, NbSx graphene composite anode materials against NMC532 single crystal in a full cell configuration using A1 electrolyte.

FIG. 7 compares the electrochemical impedance spectroscopy of NbSx coating on Li, un-treated Li (Li as such) and Li₃N treated Li as working electrode against Li as counter and reference electrode using E1 electrolyte.

FIG. 8 compares the drop in mid-value-voltage over long cycles during galvanic charge-discharge performed on the cells comprising NbSx coated Li, un-treated Li, and Li₃N treated Li as working electrode against Li as counter and reference electrodes.

### DETAILED DESCRIPTION

The present invention is predicated on the understanding that NbSₓO_{y}·zH₂O nanoparticles (where 0<x<5, 0<y<3, 0<z<10), hereafter referred as “NbSx” in this application, can play a significant role towards a high capacity (>1500 mAh/g) and stable anode material, and which can be produced effectively and consistently at scale.

Without wanting to be bound by theory, the inventors have evaluated Nb foil as a current collector for the cathode in Li—S batteries. It presented an initial low capacity of ˜200 mAh/g, which surprisingly improved after 100+ cycles to 450 mAh/g. The cell provided a stable capacity with higher cycle life (>500 cycles) at a higher rate than any other Li—S cell configuration at the time. This result led the inventors to believe that the electrochemical charge/discharge process may have created intermediary by-products from Niobium and Sulphur. It is believed that the intermediary by-products may be used to build a conductive solid electrolyte interphase (SEI) layer on the Li-metal anode, improving the stability of Li—S cells. Accordingly, the inventors are directed to further develop and synthesise NbSx material via thermochemical reaction.

In some embodiments, when NbSx was used as an artificial SEI protective layer onto Li-metal, NbSx reduced the impedance of the Li-metal anode by >100× compared to unprotected Li-metal. Further studies on the electrochemical performance revealed that this material provides a reversible charge/discharge capacity or demonstrates redox behaviour between 0.01 and 0.2 V versus Li. NbSx provided an initial charge/discharge capacity of more than 1,500 mAh/g between 0.01 and 3.0 V, with most of the discharge/charge occurring between 0.01 and 0.4 V, presenting itself as a potential anode material for alkali and alkaline-earth metal/metal-ion batteries (e.g., Li-ion, Na-ion, Al-ion, Li-metal, and Na-metal batteries). When used as an anode in the existing Li-ion batteries, it can increase the energy density by about 15-20% and improve safety by preventing dendrite formation. NbSx as anode material has the potential to out-perform Silicon anode with its higher capacity and stability.

Accordingly, the present invention provides a core-shell nanoparticle, comprising:
a) a core comprising Nb and preferably NbS₂; and
b) a shell of Formula (I):

NbSₓO_{y}·zH₂O (I)
wherein
x is a number from 0 to 5;
y is a number from 0 to 3; and
z is a number from 0 to 10.

The core-shell nanoparticle can be used as an electrochemically active material in battery applications.

As the electrochemical discharge/charge is close to 0 V vs. Li, higher cell voltage and thereby higher energy density can be achieved. High specific capacity (>1,500 mAh/g) can also be achieved, which allows development of electrodes with higher tap density, thereby high areal capacity (>4 mAh/cm²) resulting in higher energy density batteries. NbSx material can be synthesised using environmentally benign materials, is lower in cost (than Si) and avoids supply-chain issues for raw material.

The NbSx material can be used to provide high performance and durable anode for building high-energy density and long-life batteries. It is envisioned that this technology will be easy to adopt and implement; battery manufacturing companies can use this anode to replace their existing ones. In particular, NbSx can be used as an active anode material and electrode formulations for alkali and alkaline earth ion/metal batteries, for example, Li-ion, Na-ion, Li—S, Al-ion, Na-metal, Li-metal, solid-state batteries, etc. In a broader sense, NbSx can replace all the existing anode materials (like graphite and silicon) for the current Li-ion market. NbSx can directly compete with other high-capacity anode materials like silicon, silicon mono-oxide, and composites. NbSx can also be used as an anode for Na-ion batteries replacing the low capacity (˜200 mAh/g) hard carbon-based anode material used now. This will allow the construction of cell architectures for high energy density Na-ion batteries possible. The lithiated NbSx anode can also be coupled with non-lithiated cathode materials like MnO₂, NiO, FeS₂ and C-S to build Li-Ion and Li—S batteries. NbSx can be used as an artificial solid electrolyte interface material for alkali-metals like Li, Na, etc to improve the electrochemical performance of alkali-metal batteries.

In some embodiments, x, y and z are integers. In some embodiments, x is a number from 1 to 5, 2 to 5, 3 to 5, or 4 to 5. In some embodiments, y is a number from 1 to 3, or 2 to 3. In some embodiments, z is a number from 1 to 10, 2 to 10, 3 to 10, 4 to 10, 5 to 10, 6 to 10, 7 to 10, 8 to 10, or 9 to 10.

In some embodiments, x is a number from 1 to 5, and y is a number from 1 to 3. In some embodiments, x is a number from 2 to 5, and y is a number from 1 to 3. In some embodiments, x is a number from 3 to 5, and y is a number from 1 to 3. In some embodiments, x is a number from 4 to 5, and y is a number from 1 to 3. In some embodiments, x is a number from 1 to 5, and y is a number from 1 to 2. In some embodiments, x is a number from 1 to 5, and y is a number from 2 to 3.

A particle size range may be desirable to obtain proper electrical and ionic conductivities and structural stability. In some embodiments, the core-shell nanoparticle has a particle size of about 10 nm to about 1000 nm. In other embodiments, the particle size is about 10 nm to about 900 nm, about 10 nm to about 800 nm, about 10 nm to about 700 nm, about 10 nm to about 600 nm, about 10 nm to about 500 nm, about 10 nm to about 400 nm, about 10 nm to about 300 nm, about 10 nm to about 200 nm, about 10 nm to about 100 nm, about 10 nm to about 80 nm, about 10 nm to about 60 nm, or about 10 nm to about 40 nm. In some embodiments, the particle size is about 10 nm to about 280 nm, about 10 nm to about 260 nm, about 10 nm to about 240 nm, about 10 nm to about 220 nm, about 10 nm to about 200 nm, or about 40 nm to about 200 nm.

In some embodiments, the core-shell nanoparticle has a particle size of about 10 nm to about 10000 nm. In some embodiments, the core-shell nanoparticle has a particle size of about 10 nm to about 9000 nm, about 10 nm to about 8000 nm, about 10 nm to about 7000 nm, about 10 nm to about 6000 nm, about 10 nm to about 5000 nm, about 10 nm to about 4000 nm, about 10 nm to about 3000 nm, about 10 nm to about 2000 nm, about 20 nm to about 2000 nm, about 30 nm to about 2000 nm, about 40 nm to about 2000 nm, about 50 nm to about 2000 nm, about 70 nm to about 2000 nm, about 100 nm to about 2000 nm, about 200 nm to about 2000 nm, about 300 nm to about 2000 nm, about 400 nm to about 2000 nm, or about 500 nm to about 2000 nm.

In some embodiments, core-shell nanoparticle has a shell thickness of about 5 nm to about 900 nm. In other embodiments, the shell thickness is about 5 nm to about 900 nm, about 5 nm to about 800 nm, about 5 nm to about 700 nm, about 5 nm to about 600 nm, about 5 nm to about 500 nm, about 5 nm to about 400 nm, about 5 nm to about 300 nm, about 5 nm to about 200 nm, about 5 nm to about 100 nm, about 5 nm to about 80 nm, about 5 nm to about 60 nm, about 5 nm to about 40 nm, about 5 nm to about 20 nm, or about 5 nm to about 10 nm.

In some embodiments, the core-shell nanoparticle is lithiated. In this regard, the core and/or the shell of the core-shell nanoparticle is doped with lithium. Lithiation allows the material to be used as an anode against a cathode which is not litihiated like MnO₂, FeS₂, CuF₂, FeF₃ etc. The lithium present within the core-shell is active and participates in the electrochemical reaction.

In some embodiments, the core-shell nanoparticle has one Li per formula unit of the core-shell material. In some embodiments, the core-shell nanoparticle is characterised by a 1:1 molar ratio of Li to core-shell nanoparticle. In other embodiments, the molar ratio is 1.1:1, 1.2:1, 1.3:1, 1.4:1, or 1.5:1.

The present invention also provides a composite material, comprising:
a) a substrate; and
b) the core-shell nanoparticle as disclosed herein in contact with the substrate.

The composite material may be used as an anode material.

In some embodiments, the substrate is selected from graphite, graphene, an alkali metal, an alkaline-earth metal or alloy thereof, and a current collector comprising carbon, metals, intermetallic alloys and alloys and optionally, alkali and alkaline-earth metal. For example, the substrate may be Li metal.

The current collector may be a mesh, wire, foil/sheet (perforated or solid), foam, or fibre. The current collector may be porous. The current collector may comprise an electrically conductive metal, alloy, polymer or carbon.

In some embodiments, the core-shell nanoparticle is dispersed within the substrate.

The core-shell nanoparticle may be used as an active material for Lithium ion battery anode like any other anode-active materials currently used by the industry (for example graphite). Alternatively, in some embodiments, the core-shell nanoparticle is formed as a coating on the substrate. In some embodiments, the coating is characterised by a thickness of about 10 nm to about 500 μm. In some embodiments, the thickness is about 20 nm to about 500 μm, about 40 nm to about 500 μm, about 60 nm to about 500 μm, about 80 nm to about 500 μm, about 100 nm to about 500 μm, about 200 nm to about 500 μm, about 400 nm to about 500 μm, about 600 nm to about 500 μm, about 800 nm to about 500 μm, about 1 μm to about 500 μm, about 5 μm to about 500 μm, about 10 μm to about 500 μm, about 50 μm to about 500 μm, about 100 μm to about 500 μm, or about 200 μm to about 500 μm. In some embodiments, the thickness is about 5 μm to about 450 μm, about 5 μm to about 400 μm, about 5 μm to about 350 μm, about 5 μm to about 300 μm, about 5 μm to about 250 μm, about 5 μm to about 200 μm, about 5 μm to about 150 μm, about 5 μm to about 100 μm, or about 5 μm to about 50 μm. In some embodiments, the thickness is about 200 μm to about 500 μm, about 250 μm to about 500 μm, or about 300 μm to about 500 μm.

In some embodiments, when the core-shell nanoparticle is formed as a coating on the substrate, the substrate is Li metal.

In some embodiments, the core-shell nanoparticle is provided to the substrate by coating as a slurry. Accordingly, the coating further comprises other components, such as a binder and carbon black.

In some embodiments, the weight ratio of the core-shell nanoparticle in the slurry is about 20% relative to the slurry. In other embodiments, the weight ratio is about 25%, about 30%, about 35%, about 40%, about 45%, about 50%, about 55%, about 60%, about 65%, about 70%, about 75%, about 80% about 85% about 90% or about 95%. In other embodiments, the weight ratio is about 20% to about 95% relative to the slurry.

In some embodiments, the ratio of core-shell nanoparticle to carbon black is about 7:2 to about 9:0.5, or about 8:1 to about 9:0.5. In some embodiments, the ratio of core-shell nanoparticle to binder is about 7:2 to about 9:0.5, or about 8:1 to about 9:0.5.

In battery technology, binders may be present to hold the coating particles together and assist in adhering the coating to the metal or separator membrane. The binder also aids in film formation, helps form a good particle dispersion in solvent or water. The binder may also help the coating disperse to deliver a uniform slurry and discrete particles in the cathode and anode. The binder remains stable inside the harsh environment of a battery, where multiple reactions can happen. Binders may also have a certain degree of pliability so they don't crack or develop defects. Binders may be either organic solvent-based or aqueous-based. Aqueous based binders may be, but not limited to, PTFE, carboxymethyl cellulose, styrene butadiene rubber, natural binders like acacia gum or xanthum gum. Non-aqueous or organic solvent binders may be, but not limited to, PVDF, PeOZ.

In some embodiments, when the core-shell nanoparticle is formed as a coating on the substrate, the coating is characterised by a ratio of the core-shell nanoparticle to carbon black to binder of about 8:1:1, about 9:0.5:0.5, about 9.5:0.5:0, or about 6:3:1.

In some embodiments, when the core-shell nanoparticle is formed as a coating on the substrate, the substrate is carbon paper and the coating is characterised by a ratio of the core-shell nanoparticle to carbon black to binder is about 8:1:1.

In some embodiments, when the core-shell nanoparticle is formed as a coating on the substrate, the substrate is Cu foil and the coating is characterised by a ratio of the core-shell nanoparticle to carbon black to binder is about 9:0.5:0.5.

The slurry may further comprise graphene. In some embodiments, the weight ratio of the graphene in the slurry is about 60% relative to the slurry. In other embodiments, the weight ratio is about 50%, about 55% about 65% about 70%, about 75%, or about 80%. In other embodiments, the weight ratio is about 55% to about 80% relative to the slurry.

In some embodiments, when the core-shell nanoparticle is formed as a coating on the substrate, the substrate is carbon paper and the coating is characterised by a ratio of the core-shell nanoparticle to graphene to carbon black to binder is about 2:6:1:1.

Alternatively, using dry-electrode technology, a slurry may not be required for use. For example, using a hydraulic press, the core-shell material and carbon is directly pressed onto a carbon paper to obtain the anode ready for use in cell assembly.

In some embodiments, the composite material is characterised by an electric conductivity of at least about 100 times higher relative to Li metal. In other embodiments, the electric conductivity is at least about 90 times, about 80 times, about 70 times, about 60 times, about 50 times, about 40 times, about 30 times, about 20 times, or about 10 times.

The present invention also provides a battery, comprising an anode, wherein the anode comprises the core-shell nanoparticle as disclosed herein.

In some embodiments, the battery is characterised by an initial specific capacity of at least about 1,000 mAh/g. In other embodiments, the specific capacity is about 1,000 mAh/g to about 5,500 mAh/g. It is postulated that the unusually high capacity may be due to a broader conversion mechanism similar to silicon based material, which quickly fades after the first few cycles, in contrast to the normal intercalation mechanism.

In some embodiments, the battery is characterised by a minimum capacity of at least about 800 mAh/g within a voltage range of about 0.01 V to about 2.8 V.

In some embodiments, the battery is characterised by a stable specific capacity of about 1,000 mAh/g to about 5,000 mAh/g. In other embodiments, the specific capacity is about 1,000 mAh/g to about 4,500 mAh/g, about 1,000 mAh/g to about 4,000 mAh/g, about 1,000 mAh/g to about 3,500 mAh/g, about 1,000 mAh/g to about 3,000 mAh/g, or about 1,000 mAh/g to about 2,500 mAh/g.

In some embodiments, the battery is characterised by a cycling discharge specific stability of at least 45 mAh/g after 20 cycles.

In some embodiments, the battery is characterised by a mid-value-voltage of at least about 10 times lower relative to Li metal.

In some embodiments, the battery is characterised by a cycling stability of at least 300 cycles.

The present invention provide a method of synthesising a core-shell nanoparticle as disclosed herein, comprising:
a) passing sulphur vapour over a Nb metal nanoparticle under an inert condition; and
b) oxidising and hydrating the nanoparticle of step (a) in order to form the core-shell nanoparticle.

In some embodiments, the inert condition is a constant inert gas flow.

In some embodiments, the inert gas is selected from Argon, Nitrogen, or a combination thereof.

In some embodiments, step (a) is performed at about 900° C. to about 1200° C.

In some embodiments, step (b) is performed by exposing the nanoparticles of step (a) to air. This step may occur under ambient temperature and humidity. Alternatively, the rate of oxidation and/or hydration may be controlled by controlling the temperature and/or water vapour content. For example, the temperature may be about 20° C. to about 100° C., about 30° C. to about 100° C., about 40° C. to about 100° C., about 50° C. to about 100° C., about 60° C. to about 100° C., about 70° C. to about 100° C., about 80° C. to about 100° C., or about 90° C. to about 100° C. The humidity in air may be about 10% to about 99%, about 10% to about 90%, about 10% to about 80%, about 10% to about 70%, about 10% to about 60%, about 10% to about 50%, about 10% to about 40%, about 10% to about 30%, or about 10% to about 20%.

### Examples

Material Synthesis: The material was synthesised by passing sulfur vapours over a niobium metal nanopowder. The Niobium powder should preferably have the highest surface area to volume ratio as possible. The Nb powder is in the form of particles in nanoscale size.

The synthesis was performed at temperatures between 100° and 1100° C. in an inert environment under a constant flow of gas (e.g., Ar) for between 30 and 80 minutes. The synthesis is performed in a furnace capable of heat-ramping rate of 40° C./min or more. Argon was used as a carrier gas for sulfur vapours. The reaction between Niobium and sulfur occurs at the surface of the Niobium nanoparticles. NbSx was (exposed to) handled in air, thereby oxidizing and hydrating the material. Thereby, NbSx may contain oxygen and hydroxyl/water groups in its structure, thereby the molecular formula for NbSx can be written as: NbSₓO_{y}·zH₂O (where 0<x<5, 0<y<3, 0<z<10).

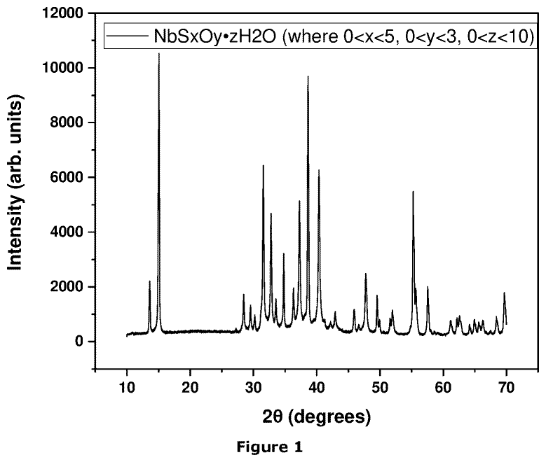

X-ray diffraction was performed at room temperature under ambient environment using a Rigaku 6th generation MiniFlex Benchtop XRD system. FIG. 1 shows the powder X-ray diffraction (XRD) of NbSx.

Further, NbSx can be lithiated electrochemically or via thermochemical routes to obtain lithiated version of NbSx to be used as an anode against non-lithiated cathode materials like MnO₂, FeS₂ and S.

NbSx can also be used in the following methods:
a) directly as an active material
b) as a composite additive into graphite or graphene to increase capacity
c) as a protective coating over an alkali and alkaline-earth metal or alloy or current collector.
   Construction of Anode with NbSx Coating
The anode is composed of NbSx coated onto a current collector adsorbed/infused/diffused/composed of carbon, metals, intermetallic alloys and alloys and optionally, alkali and alkaline-earth metal.
The current collector can be in the form of a mesh, wire, foil/sheet (perforated or solid), foam, fibre, with or without porosity and is made of electrically conductive metal, alloy, polymer or carbon structures.
The thickness of the NbSx coating is between 5 μm to 200 μm depending on the electrode design requirements.
NbSx acts as an artificial SEI protective layer, which also acts as a catalytic site that promotes the nucleation/deposition of lithium while preventing particle pulverisation over long cycles.
   Anode with Alkali and Alkaline-Earth Metals
a. In this class of anode, the current collector is embedded into an alkali and alkaline-earth metal or alloy.
b. The NbSx is coated over the alkali and alkaline-earth metal or alloy, for example, via drop/tape casting, which acts as a Li nucleation/deposition site, forming a stable SEI that supports the fast plating and stripping of the alkali and alkaline-earth metals.
c. Such an anode can be used against an electroactive material (e.g., S, C, LiMn₂O₄, and Na₂V₆O₁₆) with or without an alkali or alkaline-earth metal in its composition.
   Anode with No Alkali and Alkaline-Earth Metals
a. In this class of anode, the current collector does not contain any alkali and alkaline-earth metals or alloys.
b. The NbSx is coated directly onto the current collector via drop/tape casting. Coated NbSx acts as a locus for the nucleation/conversion of alkali and alkaline-earth metals to form a stable SEI.
c. When this class of anode is used against an alkali or alkaline-earth metal-containing cathode (like Nickel Manganese Cobalt (NMC), LiMn₂O₄, and LiFePO₄) in an electrochemical cell, the alkali or alkaline-earth metal-ions undergoes conversion reaction with NbSx, which is adsorbed/infused/diffused onto/into the current collector. Thereby, a stable SEI layer is formed, which further allows the platting/stripping of a thicker layer of alkali or alkaline-earth metal, thereby forming the anode in situ.

NbSx can be used as an active material for anode or as an additive in composites with existing anode active materials to increase the capacity or as an artificial solid electrolyte interface protective coating layer for alkali and alkaline-earth metals used as an anode for batteries.

NbSx in Batteries: NbSx as an Active Material and/or as a Composite Additive for Anode

Electrochemical characterisation was performed using the as-synthesised NbSx. Galvanic charge and discharge are performed to obtain the specific capacity of the NbSx and evaluate the rate and cycle life performance.

The working electrode or the anode are fabricated in the following two configurations:

### Anode Configurations

Coatings of a slurry comprising of NbSx, carbon black, and binders in the ratios of:
1) 8:1:1 ratio over carbon paper (Avcarb P50)
2) 9:0.5:0.5 over Cu foil

The electrodes were dried overnight at a temperature of 50° C.

NMC532 cathodes were prepared by tape-casting a water-based slurry comprising of NMC532 single crystal, carbon black, binders in a 8:1:1 ratio over carbon paper (Avcarb P50).

The cells were tested using two electrolyte systems, one based on carbonate solvent and another on ether solvent named A1 and E1.
A1 electrolyte: 1M LiPF₆ dissolved in carbonate solvent.
E1 electrolyte: 1M LiTFSI dissolved in ether solvents.

Cell architecture: All coin cells were made using standard CR2032 coin cell components made of stainless steel. Celgard 2325 separator made of polypropylene and 40 ul of electrolyte was used for all the experiments.
Half cells: Half cells were constructed by using Li-metal chips as the counter and reference electrodes against the working electrodes. The working electrodes used here are NbSx coated on carbon and copper and NbSx graphene composite coated over carbon paper.
Full cells: Full cells were constructed by using NMC532 cathode against graphite, NbSx and NbSx graphene composite anodes using A1 electrolyte.

### Analysis of the NbSx's Electrochemical Performance:

### 1) NbSx as an Active Material for Anode:

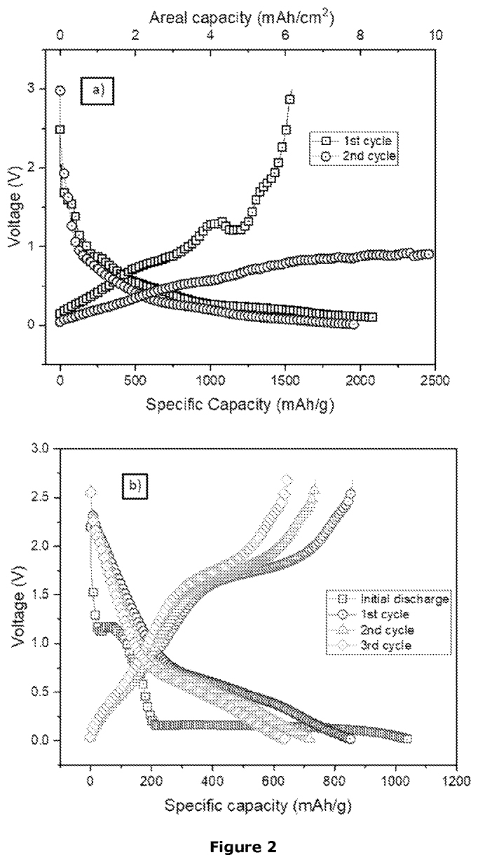

As can be seen from the charge-discharge plots shown in FIG. 2a (galvanic charge-discharge behaviour), when NbSx was used as an active material coated over carbon paper, it delivers a specific capacity of >2,000 mAh/g and >6 mAh/cm² in E1 electrolyte. The capacity is based on NbSx active material alone. FIG. 2b demonstrates the galvanic charge-discharge performance of NbSx coated over copper current collector delivers an initial specific discharge capacity of 1,050 mAh/g and a first cycling-specific capacity of 850 mAh/g in A1 electrolyte. The higher capacity of NbSx in ether-based solvents compared to carbonate-based solvents is due to the higher stability of intermediary conversion products of NbSx in ether solvents.

Nevertheless, NbSx in its pure form can provide a minimum capacity of above 800 mAh/g within the voltage range of 0.01 V to 2.8 V in both ether- and carbonate-based electrolytes, which is higher than commercial graphite and competitive to silicon in terms of stability and areal capacity.
2) NbSx composites to increase capacity:

A composite of NbSx and graphene was prepared by sonication, in a weight ratio of 1:3, followed by drying in a vacuum oven to obtain the composite powder. The anode was fabricated by tape-casting a slurry comprising NbSx/graphene composite, carbon black, binders in a 8:1:1 ratio over carbon paper (Avcarb P50).

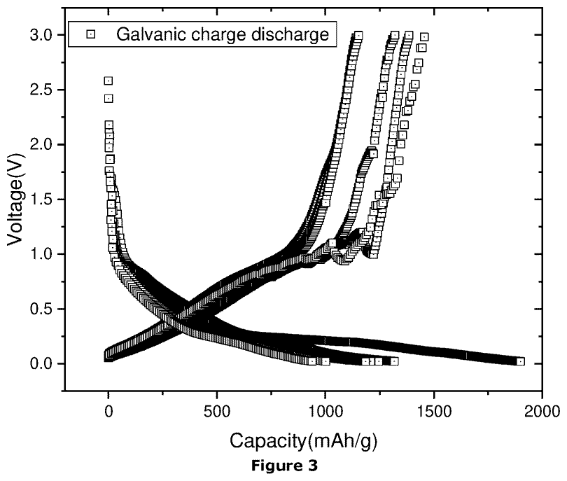

The galvanic charge-discharge performance of the NbSx/graphene composite material was first evaluated in the half cell configuration, followed by testing in full cell configuration. NbSx/graphene composite provided an initial specific capacity of 1,899 mAh/g and a stable specific capacity of 1,000 mAh/g after 5 cycles. FIG. 3 shows the galvanic charge-discharge behaviour of NbSx graphene composite coated over carbon current collector using A1 electrolyte. The specific capacity is based on the total weight of the composite NbSx and graphene.

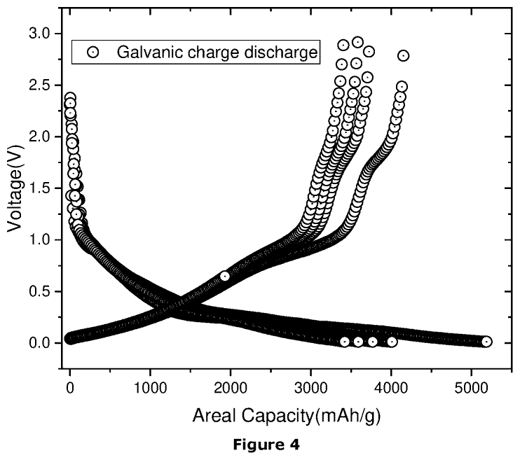

When carbon fibre was used as an interlayer between the working electrode and the separator, it improved the stability and capacity retention of NbSx. In such a cell configuration, NbSx anode prepared as described in the anode configuration 2, demonstrates an initial specific capacity of 5,187 mAh/g and stable specific capacity of >3,000 mAh/g after the first cycle. FIG. 4 shows the galvanic charge-discharge behaviour of NbSx coated over copper current collector using A1 electrolyte and a carbon fibre interlayer between Celgard 2325 separator and anode. The specific capacity is based on the weight of NbSx active material.

Thus using carbon nano-objects as additives or in composites with NbSx can improve the stability and capacity of the anode material.

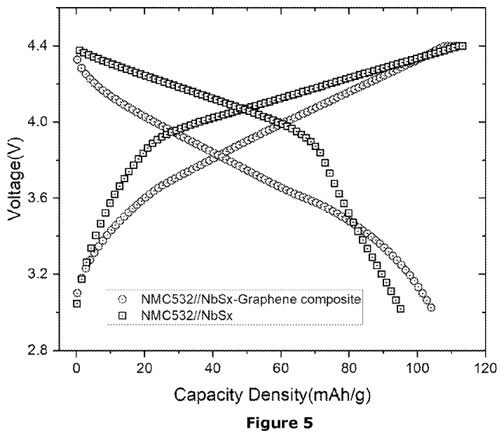

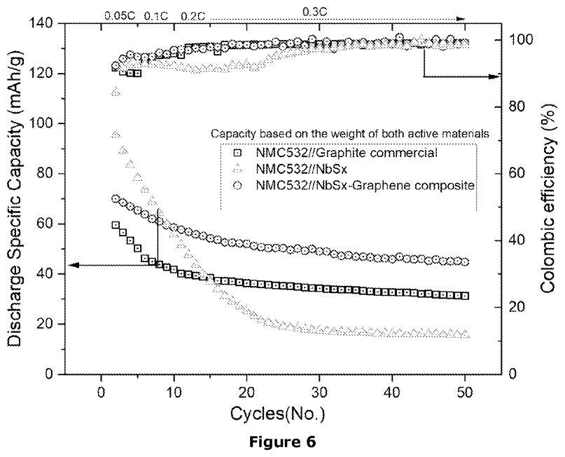

Further, full cell studies were performed to compare the rate, cycle life and Coulombic efficiency of NbSx, NbSx/graphene composite and graphite against NMC532 as the cathode. FIG. 5 shows the galvanic charge-discharge behaviour of NbSx and NbSx graphene composite anode materials using A1 electrolyte. NbSx presents higher nominal voltage and similar capacities. Thereby, NbSx has a higher energy density than NbSx/graphene composite. On the other hand, NbSx/graphene composite demonstrates better rate performance, Coulombic efficiency and cycling stability than NbSx and commercial graphite. FIG. 6 shows a comparison of the rate, cycling performance and Coulombic efficiency of commercial graphite, NbSx, NbSx graphene composite anode materials against NMC532 single crystal in a full cell configuration using A1 electrolyte. The capacity is based on the total weight of the cathode active and anode active materials.

### NbSx as an Artificial Protective SEI Layer

Typically, Li-metal anode used, for example, in Li—S and most solid-state batteries, have an excess of about 500% Li. This is to ensure that there is always a layer of fresh lithium over which the stripped lithium can plate themselves during the charge-discharge process. Excess lithium increases the cost and decreases the battery's energy density, thereby defying the very purpose of using a high capacity anode. Bare Li suffers from massive volume changes upon repeated plating and stripping, during which a stable solid electrolyte interphase (SEI) could fail to form on the surface. The constant exposure of Li-metal to the electrolytes causes the formation of insulating products and electrolyte consumption, leading to low Coulombic efficiencies and poor-cycling performance. Modified electrolytes have been proposed to regulate the electrolyte/electrode interface and induce a rigid SEI upon Li plating. Many studies reveal active electrolyte ingredients are constantly consumed upon cycling, and thus raises concerns on the lifespan of practical Li-metal cells adopting modified electrolytes. Carbon materials and polymers are frequently employed to build physical layers to prevent dendrite penetration in Li anodes, decreasing the plating and stripping efficiency on Li-metal, thereby creating Li isolation zones on the anode.

An ideal artificial SEI layer should actively bond with plated Li to regulate the deposition behaviours while maintaining the integrity upon extended cycling.

We address the above problem differently by providing catalytic and electroconductive sites at NbSx for the plating and stripping of alkali and alkaline-earth metals.

The as-synthesised NbSx was characterised using galvanic charge-discharge and electrochemical impedance spectroscopy. Galvanic charge-discharge was also performed to evaluate NbSx as a protective coating for Li-metal through the drop in mid-value voltage over long cycles.

Working electrodes were tested and compared for their electrochemical performance:
1) Artificial protective SEI layer of NbSx on Li-metal
2) Artificial protective SEI layer of Li₃N on Li-metal
3) Li-metal as received (no coatings)

The NbSx artificial protective SEI layer on Li-metal was coated by drop-casting a 15:100 ratio (w: v) of NbSx and NMP over a 16 mm diameter Li-metal chips. Li-metal chips were purchased from MTI corporation. The coated Li-metals were dried thoroughly before use.

The Cells were Tested Using E1 Electrolytes.

Cell architecture: All coin cells were made using standard CR2032 coin cell components made of stainless steel, Celgard 2325 separator and 40 ul of electrolyte. Half cells were constructed using Li-metal chips as the counter and reference electrodes against the working electrodes described above.

### Electrochemical Analysis of the NbSx as a Protective Coating:

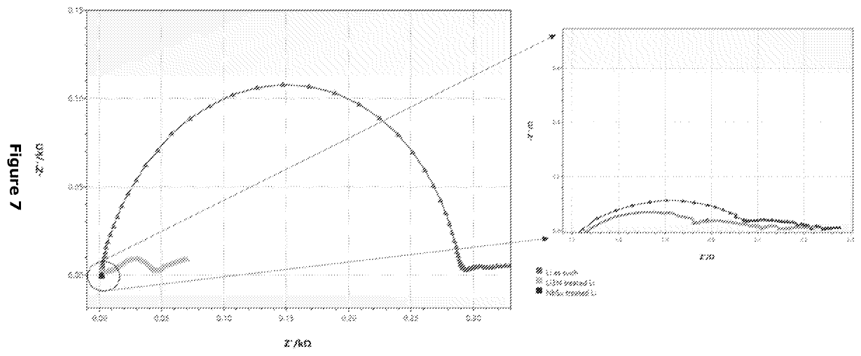

FIG. 7 shows the electrochemical impedance spectroscopy of NbSx coated on Li, un-coated Li (Li as such) and Li₃N coated Li as working electrode against Li as counter and reference electrode. The electrochemical impedance spectroscopy comparing the different working electrodes shows that NbSx coated Li has 25× and >100× better conductivity than Li₃N coated Li and commercial Li metal chip, respectively.

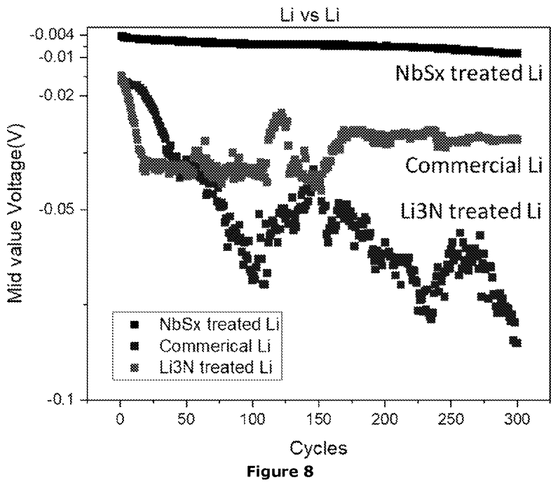

Further, to evaluate and compare the long cycling stability among the working electrodes, galvanic charge-discharge was performed for more than 300 cycles. FIG. 8 shows mid-value-voltage over long cycles during galvanic charge-discharge was performed using NbSx coated Li, un-coated Li and Li₃N coated Li as working electrode against Li as counter and reference electrode. NbSx coated Li shows higher stability over long cycles with ˜10× lower mid-value voltage indicating the high conductivity for NbSx treated Li compared to the other two working electrodes. Thus, NbSx proves to create a better artificial protective SEI layer for Li metal.

It will be appreciated that many further modifications and permutations of various aspects of the described embodiments are possible. Accordingly, the described aspects are intended to embrace all such alterations, modifications, and variations that fall within the spirit and scope of the appended claims.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

Throughout this specification and the claims which follow, unless the context requires otherwise, the phrase “consisting essentially of”, and variations such as “consists essentially of” will be understood to indicate that the recited element(s) is/are essential i.e. necessary elements of the invention. The phrase allows for the presence of other non-recited elements which do not materially affect the characteristics of the invention but excludes additional unspecified elements which would affect the basic and novel characteristics of the method defined.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

1. A core-shell nanoparticle, comprising:
a) a core comprising Nb and preferably NbS₂; and
b) a shell of Formula (I):
NbSₓO_{y}·zH₂O (I)
wherein
x is a number from 0 to 5;
y is a number from 0 to 3; and
z is a number from 0 to 10.

2. The core-shell nanoparticle of claim 1, wherein x, y and z are integers.

3. The core-shell nanoparticle of claim 1, wherein the core-shell nanoparticle has a particle size of about 10 nm to about 10000 nm.

4. The core-shell nanoparticle according to claim 1, wherein core-shell nanoparticle has a shell thickness of about 5 nm to about 900 nm.

5. The core-shell nanoparticle according to claim 1, wherein the core-shell nanoparticle is lithiated.

6. A composite material, comprising:
a) a substrate; and
b) the core-shell nanoparticle according to claim 1 in contact with the substrate;
wherein the substrate is selected from graphite, graphene, an alkali metal, an alkaline-earth metal or alloy thereof, and a current collector comprising carbon, metals, intermetallic alloys and alloys and optionally, alkali and alkaline-earth metal.

7. The composite material of claim 6, wherein the core-shell nanoparticle is dispersed within the substrate.

8. The composite material of claim 6, wherein the core-shell nanoparticle is formed as a coating on the substrate, wherein the coating is characterized by a thickness of about 10 nm to about 500 μm.

9. (canceled)

10. The composite material of claim 8, wherein when the core-shell nanoparticle is formed as a coating on the substrate, the substrate is Li metal.

11. The composite material of claim 8, wherein when the core-shell nanoparticle is formed as a coating on the substrate, the substrate is carbon paper and the coating is characterised by a ratio of the core-shell nanoparticle to carbon black to binder is about 8:1:1.

12. The composite material of claim 8, wherein when the core-shell nanoparticle is formed as a coating on the substrate, the substrate is Cu foil and the coating is characterised by a ratio of the core-shell nanoparticle to carbon black to binder is about 9:0.5:0.5.

13. The composite material of claim 8, wherein when the core-shell nanoparticle is formed as a coating on the substrate, the substrate is carbon paper and the coating is characterised by a ratio of the core-shell nanoparticle to graphene to carbon black to binder is about 2:6:1:1.

14. The composite material according to claim 6, wherein the composite material is characterised by an electric conductivity of at least about 100 times higher relative to Li metal.

15. A battery, comprising an anode, wherein the anode comprises the core-shell nanoparticle according to claim 1.

16. The battery of claim 15, wherein the battery is characterised by at least one of the following:
a) a minimum capacity of at least about 800 mAh/g within a voltage range of about 0.01 V to about 2.8 V;
b) a stable specific capacity of about 1,000 mAh/g to about 5,000 mAh/g;
c) a cycling discharge specific stability of at least 45 mAh/g after 20 cycles;
d) a mid-value-voltage of at least about 10 times lower relative to Li metal;
e) a cycling stability of at least 300 cycles.

17-20. (canceled)

21. A method of synthesising a core-shell nanoparticle according to claim 1, comprising:
a) passing sulphur vapour over a Nb metal nanoparticle under an inert condition; and
b) oxidising and hydrating the nanoparticle of step (a) in order to form the core-shell nanoparticle.

22. The method of claim 21, wherein the inert condition is a constant inert gas flow.

23. The method of claim 22, wherein the inert gas is selected from Argon, Nitrogen, or a combination thereof.

24. The method according to claim 21, wherein step (a) is performed at about 900° C. to about 1200° C.

25. The method according to claim 21, wherein step (b) is performed by exposing the nanoparticles of step (a) to air.
